(19) United States
(12) Patent Application Publication
(10) Pub. No.: US 2017/0345746 A1
(43) Pub. Date: Nov. 30, 2017

(54) INTEGRATED CIRCUIT PACKAGE WITH SOLDER BALLS ON TWO SIDES

(71) Applicant: FREESCALE SEMICONDUCTOR, INC., AUSTIN, TX (US)

(72) Inventor: Weng Foong Yap, CHANDLER, AZ (US)

(21) Appl. No.: 15/165,511

(22) Filed: May 26, 2016

(51) Int. Cl. H01L 23/498; H01L 21/78; H01L 23/31; H01L 21/56

(52) U.S. Cl. CPC H01L 23/49816; H01L 23/49822; H01L 21/561; H01L 21/78; H01L 23/3114

(57) ABSTRACT

An integrated circuit package with solder balls on two major sides of the package and a method of making. The integrated circuit package includes at least one die encapsulated in an encapsulant. A work piece panel is formed with encapsulated die. Solder balls are attached to two major opposing sides of the panel. Afterwards, the panel is singulated into individual integrated circuit packages.

### BACKGROUND OF THE INVENTION

### Field of the Invention

This invention relates in general to integrated circuit packages with solder balls.

### Description of the Related Art

An integrated circuit package includes a device such as a semiconductor die encapsulated in an encapsulant that allows it to be utilized in a system (e.g. an electronic system such as a computer, phone, laptop, or other system utilizing a device such as an automobile, appliance, robotic equipment etc.). The integrated circuit package may include external terminals such as solder balls for providing communication signals and power to the device.

### BRIEF DESCRIPTION OF THE DRAWINGS

The present invention may be better understood, and its numerous objects, features, and advantages made apparent to those skilled in the art by referencing the accompanying drawings.

FIGS. 1-5 set forth cutaway side views of various stages in the manufacture of an integrated circuit package according to one embodiment of the present invention.

FIGS. 6-7 set forth cutaway side views of various stages in forming a system that incorporates an integrated circuit package according to one embodiment of the present invention.

The use of the same reference symbols in different drawings indicates identical items unless otherwise noted. The Figures are not necessarily drawn to scale.

### DETAILED DESCRIPTION

The following sets forth a detailed description of a mode for carrying out the invention. The description is intended to be illustrative of the invention and should not be taken to be limiting.

As disclosed herein, an integrated circuit package includes solder balls independently attached to a first major surface of the integrated circuit package and a second plurality of solder balls independently attached to a second major surface of the integrated circuit package. The integrated circuit package includes at least one die encapsulated in an encapsulant of the integrated circuit package. In one embodiment, the package is formed by forming an encapsulated panel that includes die and then independently attaching solder balls to both major sides of the panel. After attaching the solder balls, the panel is singulated into integrated circuit packages with solder balls located on both major sides of the package. In some embodiments, providing an integrated circuit package with solder balls on both sides of the package allows structures with circuitry to be attached to the top and bottom of the package without having to independently attach solder balls to either structure. Accordingly, a system manufacture or component supplier can acquire the integrate circuit package and incorporate it into its products without having to utilize solder ball formation and attachment equipment.

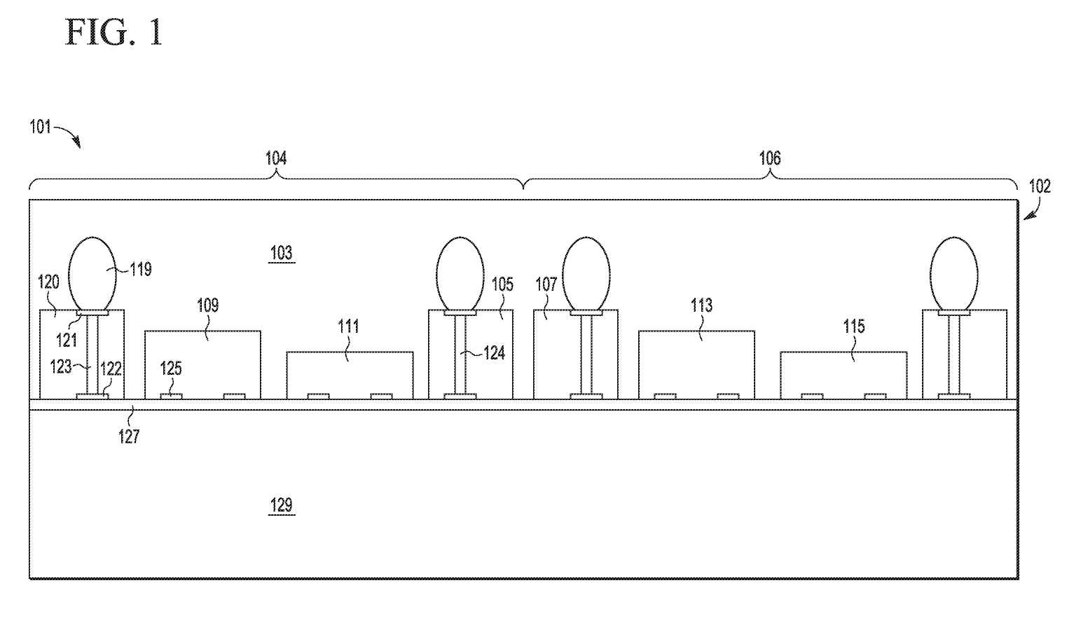

FIG. 1 is a cut away side view of a stage in the manufacture of an integrated circuit package according to one embodiment of the present invention. Work piece panel 101 includes an encapsulated panel 102 formed on a carrier 129. In the embodiment shown, the panel 102 is attached to carrier 129 with an adhesive structure 127. In one embodiment, adhesive structure 127 includes an adhesive tape with adhesive material on both sides, but in other embodiments may include only adhesive material.

In the embodiment shown, panel 102 includes two package sites 104 and 106 in which separate integrated packages will be formed from. However, other embodiments may include a different number of package sites per panel. In the embodiment shown, each package site (104, 106) includes two die (109, 111, 113, and 115) and a ring structure (105 and 107) that surrounds the die of the package site. For example, ring structure 105 surrounds die 109 and 111. Since FIG. 1 is a cutaway side view, ring structure 105 appears as two different structures in FIG. 1 with each structure located on each side of die 109 and 111. Ring structure 105 includes a dielectric material (120) (e.g. ceramic, polymer, oxide) with conductive pillars (123, 124) embedded therein. Pillars extend from a bottom conductive pad (122) to a top conductive pad (121) of the ring structure 105. In one embodiment, pillars 123, 124 are made of copper, but may be made of other conductive materials (e.g. gold, silver, aluminum, solder) in other embodiments. In one embodiment, pads (121) provide a surface for the subsequent attachment of solder balls (119). In some embodiments, pads 121 also provide a redistribution function where the location of the solder balls (119) can be offset from the location of the pillars (123). In some embodiments, bottom pads (122) also provide a redistribution function. In embodiment shown, ring structures 105 and 107 are implemented as separate pieces, but may be integrated as one piece in other embodiments.

Panel 102 is formed by placing the die (e.g. 109, 111, 113, and 115) active side down on adhesive structure 127. The die include conductive pads (125) on the active side. The pads (125) are coupled to circuitry in the die. The ring structures (105) are then placed around the die (109, 111) of a package site (104). After the attachment of the ring structures, solder balls (119) are attached to the top pads (121) of the ring structures (105). In one embodiment, the solder balls (119) are placed on the top pads (121) by a pin placement technique. However, in other embodiments, the solder balls can be attached by other techniques in other embodiments (e.g. by vacuum deposition / ball drop / jet printing). After the placement of the solder balls (119), the solder balls are bonded to pads by a reflow process were the temperature is elevated (e.g. by placing the work piece in a solder oven) to liquefy the solder to bond the solder balls (119) to pads (121). In some embodiments, flux may be applied to the pads (121) prior to the placement of the solder balls (119).

After the attachment of the solder balls (119), the die (109, 111, 113, and 115), ring structures (105), and solder balls (119) are encapsulated in an encapsulant 103. In one embodiment, encapsulant 103 is a typical mold compound or liquid epoxy encapsulant material used in an integrated circuit package as a dielectric or insulator for electrical conductive wires or die within the integrated circuit package. Some example encapsulants include silica-filled epoxy molding compounds, plastic resins, and polymeric materials such as silicones, polyimides, phenolics, and polyurethanes. In one embodiment, the encapsulant is applied by a mold transfer process, but may be applied by another processes in other embodiments (e.g. compression molding, transfer molding, center gate molding, printing, or spin application).

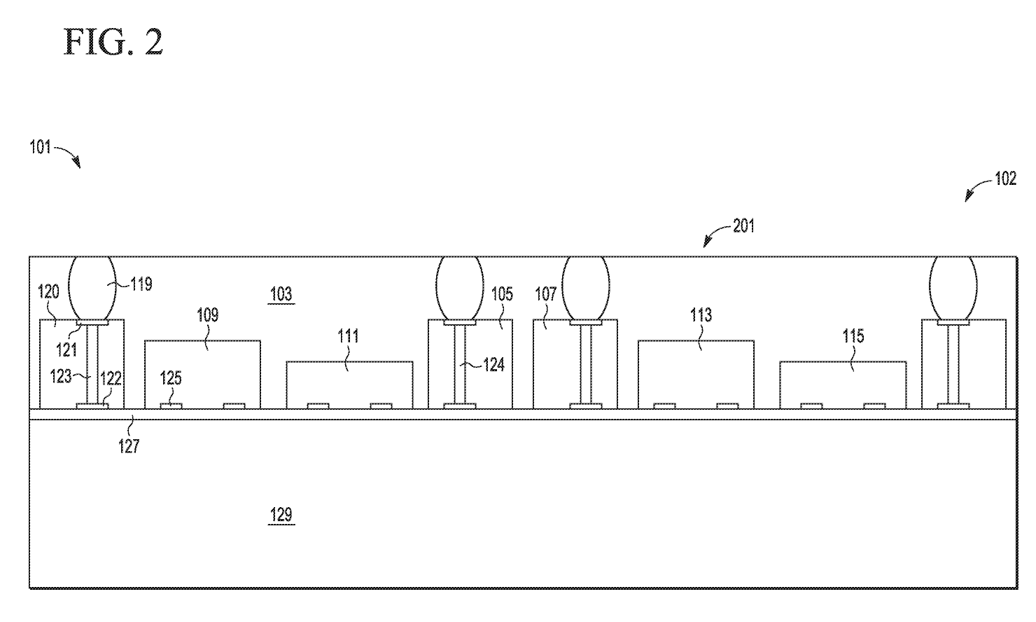

FIG. 2 shows a cutaway side view of the panel 102 after a top portion of panel 102 is removed to expose the solder balls (119). The top portion of panel 102 can be removed by a grinding, polishing, lapping, or etching process. For each die 109, 111, 113, and 115, FIG. 2 shows encapsulant material of encapsulant 103 located next to at least three sides of each die in a direction that is orthogonal from the side and extending out away from the die from the side. Referring to die 113 in FIG. 2, arrows are shown for three directions that are orthogonal from a side of die 113 and extending out away from the die from the side. Encapsulant material is also located next to the side coming out of the page and going into the page relative to the view shown in FIG. 2 (not shown in the cutaway view of FIG. 2).

In other embodiments, the encapsulated panel may have other configurations and/or have other devices. For example, each package site (104, 106) may have a different number of die (one or three or more). Also, the panel may include a ground plane embedded therein. In addition, each conductive pillar may be individual placed on the carrier instead of being part of a ring structure as shown. Also, the panel may include other types of devices such as discrete devices (e.g. an antennae). Some embodiments may not include embedded solder balls (119). In some embodiments, pads (121) may be exposed at the top of panel 102. Still in other embodiments, the encapsulant may be removed down to expose the surface of the tallest die. Still in other embodiments, the encapsulant is not removed from the encapsulated structure after encapsulation. In some embodiments, the embedded solder balls (119) may be exposed by laser ablation or localized etching similar to a TMV process (Through Mold Via).

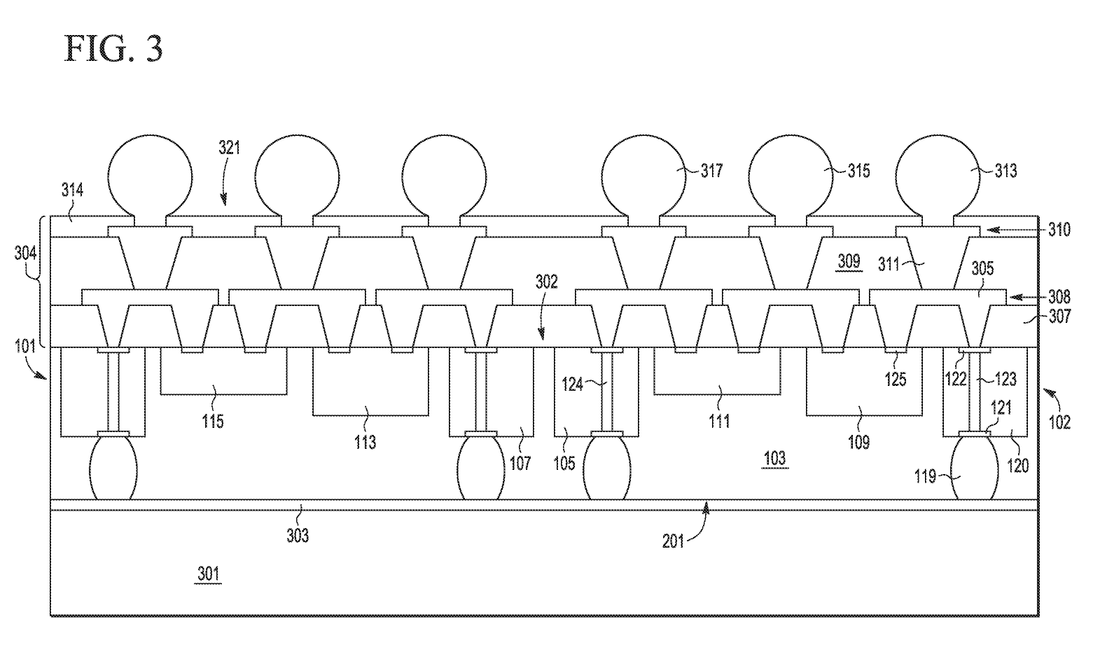

FIG. 3 is a cutaway side view of work piece panel 101 after a redistribution layer 304 is added to a major side of panel 102 and solder balls are added to the corresponding major side of the work piece panel 101. Prior to the stage of FIG. 3, panel 102 is removed from carrier 129 by releasing adhesive structure 127. Major side 201 of panel 102 is attached to carrier 301 (in FIG. 3) with adhesive structure 303. Thus, panel 102 is inverted in FIG. 3 from its position shown in FIG. 2. After the removal of carrier 129 and after being placed in the inverted position of FIG. 3, major side 302 of panel 102 is exposed where the bond pads (e.g. 125) of die 109, 111, 113, and 115 are exposed. After the placement on carrier 301, a redistribution layer 304 is formed on major side 302 of panel 102.

In the embodiment shown, redistribution layer 304 is formed by first forming a layer 307of dielectric material on side 302. In one embodiment, dielectric layer 307 is made of an oxide, but may be made of other materials. Openings are made in layer 307 to expose the pads (e.g. 125) of the die and bottom pads (122) of the ring structures (e.g. 105). After the formation of the openings in layer 307, a layer 308 of conductive material is formed over layer 307. Layer 308 is made of a conductive material (e.g. copper, aluminum, tungsten) that electrically contacts the bond pads (125) of die 115, 113, 111, and 109 and the bottom pads (122) of the ring structures 105 and 107. In one embodiment, layer 308 is made of one material, however, in other embodiments, layer 308 may be made of multiple layers of different conductive materials (e.g. may include a barrier layer).

In the embodiment shown, layer 308 completely fills the openings in layer 307. However, in other embodiments, layer 308 would be thinner and not completely fill the openings.

After the deposition of layer 308, layer 308 is planarized and then patterned to form electrical interconnects (e.g. 305) that are electrically coupled to bond pads (e.g. 125) and/or pads (e.g. 122) of panel 102. After patterning, a second dielectric layer 309 is formed over layers 307 and 308. Openings are formed in layer 309 to expose portions of interconnects (305) of layer 308 and to provide routing for subsequently formed vias to solder ball locations. A layer 310 of conductive material is deposited on layer 309 and in the openings to electrically contact the interconnects (305) of layer 308. After the deposition of layer 310, layer 310 is planarized and then patterned to form interconnects (311). A dielectric layer 314 is formed over layer 310 and layer 309. Openings are subsequently formed in layer 314 to expose the interconnects (311) of layer 310 at the locations of the subsequently attached solder balls (313). Redistribution layer 304 may have other configurations in other embodiments. For example, the redistribution layer may have a greater or lesser number of interconnect layers. Also, the conductive structures and dielectrics may be have different forms, made of different materials, and/or be formed by different processes.

Solder balls (313, 315, and 317) are attached to the major side 321 of work piece panel 101. In the embodiment shown, solder balls (313, 315, 317) are attached to the exposed conductive surface of interconnects (311) through the openings in layer 314.

In one embodiment, to attach the solder balls, an adhesive flux is applied to the conductive surfaces of the interconnects (311) e.g. by a solid base printing process or a pin application process. The solder balls (previously formed) are picked up from a tray by a vacuum device with openings corresponding to the locations of the solder balls on work piece panel 101. The vacuum device is brought to major side 321 of work piece panel 101 where the solder balls are then applied to the flux at the desired locations and the vacuum is removed to release the solder balls. In some embodiments, solder balls are jet printed on the desired locations or transferred through a cavity matched stencil. The solder balls remain at the desired locations due to flux being somewhat tacky. Afterwards, work piece panel 101 is placed in a reflow oven where it's heated to an elevated temperature above the solder solidus temperature (e.g. 217-221 C for some typical lead-free solder) temperature of the solder to bond the solder balls (313) to the conductive structures (311) of layer 310. The specific elevated temperature depends upon the composition of the solder being used. In some embodiments, a cleaning process may be performed prior to reflow if water soluble flux is used.

In some embodiments, the solder balls may be attached by other methods (e.g. by a manual ball drop process or jet printing). For example, the solder balls can be formed and attached to the work piece by plating copper pillars with solder caps, solder paste printing, or a bumping process. In such processes, discrete portions of solder are applied to the desired areas and reflowed to form a solder ball at the desired structure.

The attaching of the solder balls by the processes described above can be characterized as “independently attaching” the solder balls to the work piece panel. Independently attaching means that the solder balls are bonded only to the work piece panel as a result of the attachment process and not to another structure separate from the work piece panel. For example, if the solder balls were also bonded to another integrated circuit package in addition to the work piece panel as a result of the bonding process, then the solder balls would not be attached by an “independently attaching” process. An example of where solder balls are not attached by an independently attaching process is where the solder balls are first bonded to another package and then are brought to the pads of the work piece panel; where after reflow, the solder balls are bonded to both the work piece panel and the other package.

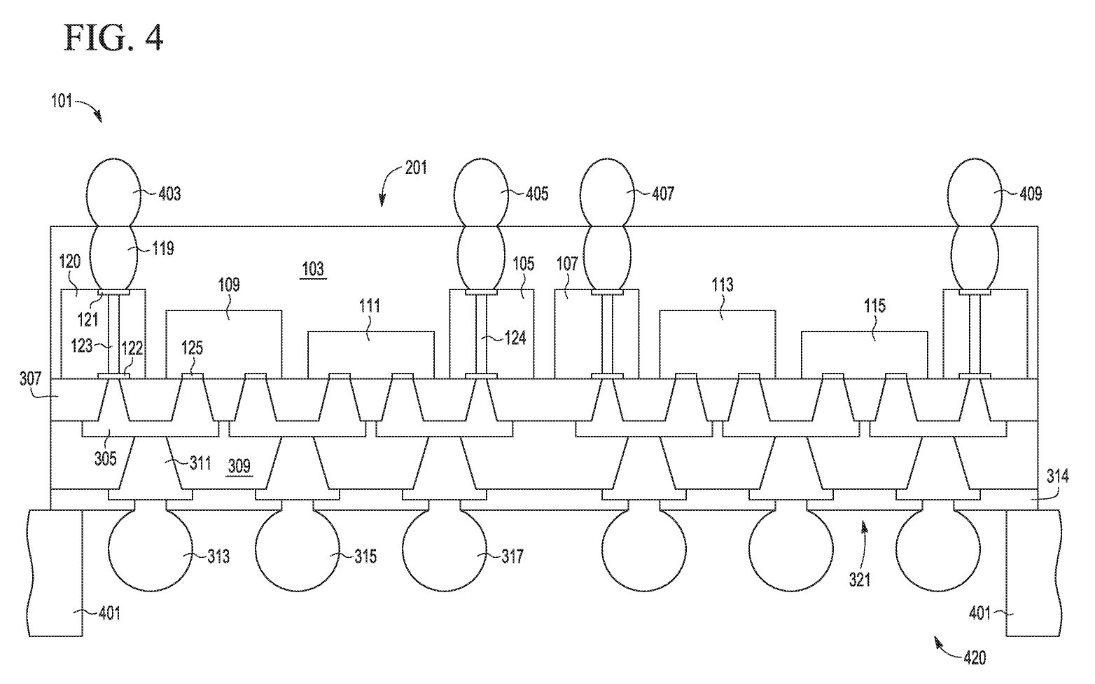

FIG. 4, shows a cutaway side view of work piece panel 101 after work piece panel 101 is removed from carrier 301, inverted, and placed on carrier 401. Carrier 401 is thicker than the distance that solder balls (313) extend from major side 321 of panel 101. In the embodiment shown, carrier 401 includes an opening 420 where the solder balls (313) attached to side 321 reside so that no bottom pressure is applied to them during the attachment of solder balls to major side 201 of work piece panel 101. In the embodiment shown, all of the solder balls attached to side 321 reside in opening 420. However, in other embodiments, carrier 401 may include multiple openings where one or more solder balls attached to side 321 would be located in each of the openings.

Solder balls 403, 405, 407, and 409 are attached by an independently attaching process to the exposed portions of the encapsulated solder balls (119). In one embodiment, solder balls 403, 405, 407, and 409 are attached by the same process as solder balls 313, 315 and 317. For example, flux may be applied to the exposed surfaces of the encapsulated solder balls (119). Afterwards, solder balls 403, 405, 407, and 409 are brought to the locations of the applied flux. The work piece is then heated in a solder oven where the solder balls bond to the exposed solder balls (119). However, in other embodiments, the solder balls may be attached by different independently attaching processes. In some embodiments, a redistribution layer (similar to redistribution layer 304) can be formed on major side 201 prior to the attachment of solder balls 403, 405, 407, and 409.

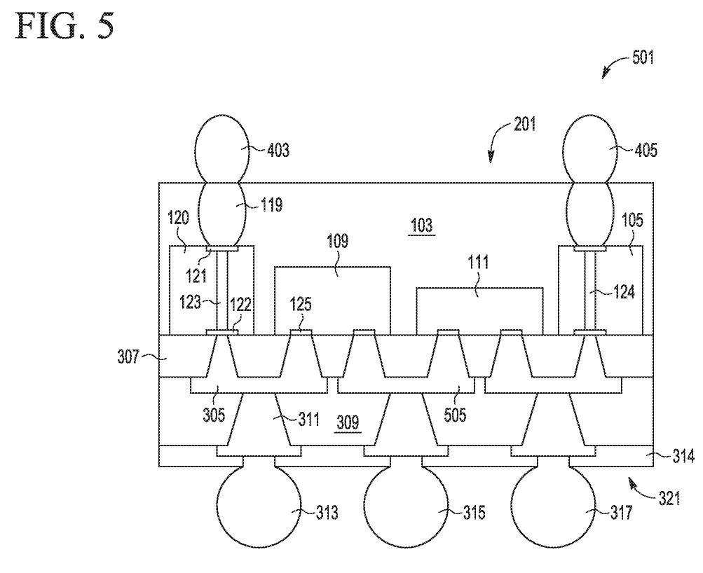

After the stage of FIG. 4, work piece panel 101 is then singulated into individual integrated circuit packages (e.g. package 501) as shown in FIG. 5. In some embodiments, panel 101 can be singulated with a saw, laser, or liquid jet. Package 501 includes solder balls bonded to conductive structures of both its major sides (201 and 321). Package 501 includes multiple integrated circuit die (109 and 111) electrically coupled together (via interconnects 305) and to solder balls (403 and 405) on side 201 and to solder balls 313, 315, and 317 on side 321.

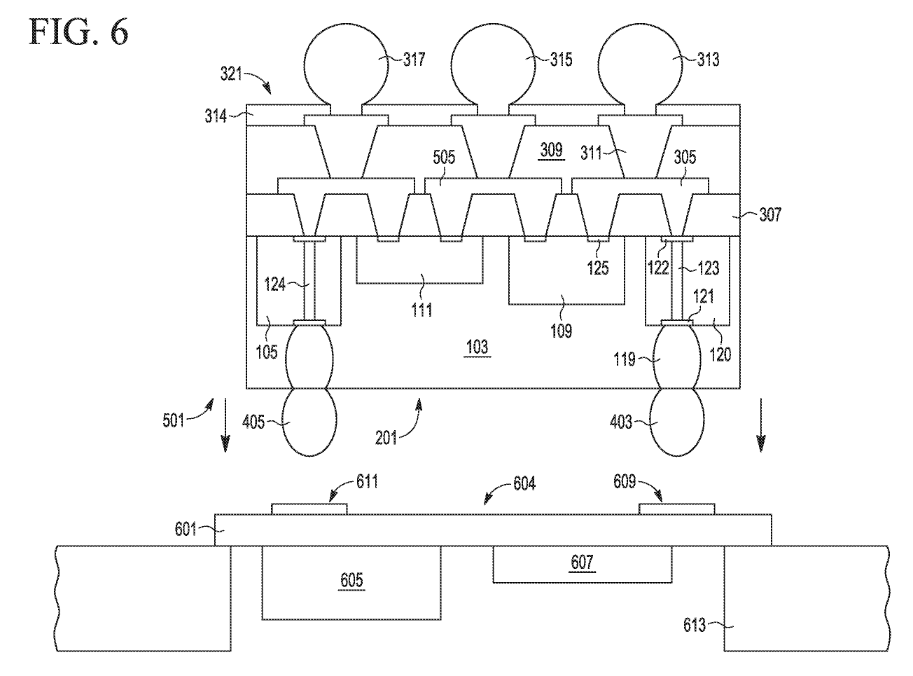

FIG. 6 shows a cutaway side view where package 501 is being brought into contact with circuit board 601. In the embodiment shown, circuit board 601 includes electrically conductive pads 611 and 609 located on side 604 of circuit board. Pads 611 and 609 are electrically coupled to integrated circuit packages 605 and 607 attached to side 606 of board 601. Circuit board 601 includes internal vias and interconnects (not shown) for electrically coupling pads 611 and 609 to packages 605 and 607. Also not shown are terminals (pads, leads) of packages 607 and 605 that are bonded to pads (not shown) located on board 601. Circuit board resides on carrier 613 during the attaching process. After solder balls 403 and 405 are brought into contact with pads 611 and 609, the solder balls are reflowed (in a reflow oven) to bond the solder balls to pads 611 and 609 to attach the integrated circuit package 501 to board 601. Prior to the stage of FIG. 6, solder paste or flux (not shown) may be applied to pads 609 and 611.

In other embodiments, the integrated circuit packages 607, 605 (and other devices) may be bonded to the solder balls (403, 405, 407, and 409) located side 201. In such embodiments, board 601 would be omitted. With such an embodiment, side 201 of package 501 may include a redistribution layer (not shown).

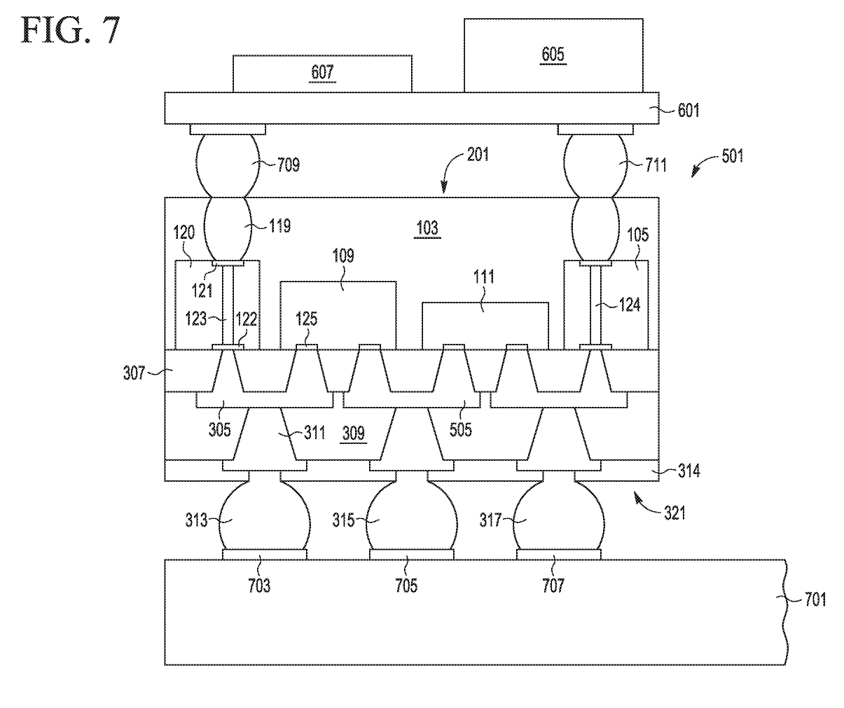

FIG. 7 is a cutaway side view after package 501 is attached to a system board 701. System board 701 includes bond pads 703, 705, and 707 that solder balls 313, 315, and 317, respectively, are bonded to. In one embodiment, flux is applied to the pads where the solder balls are brought in contact with the flux and reflowed.

In one embodiment, board 701 is a circuit board for a system that implements package 501 and board 601. In one embodiment, the attachment of board 601 and board 701 are made by the same system manufacturer. In other embodiments, board 601 is attached to package 501 by a component manufacturer who then delivers board 601 and package 501 to the system manufacturer who then attaches package 501 (with board 601 attached) to board 701. In one embodiment, board 701 includes other integrated circuit packages and devices (not shown) of the system attached to it. Board 701 includes electrically conductive structures (not shown) such as vias and interconnects for coupling the devices of board 601 and package 501 with other devices (not shown) of system board 701.

In one embodiment, die 109 includes a data processor and die 111 includes a memory (e.g. DRAM, SRAM, Flash, PMIC (power management IC)). Package 501 may include other types of die e.g. such as power control device. In such an embodiment, package 501 would implement a general processing system having I/O solder balls (e.g. 313, 315, and 317) for communicating with a system processor (not shown) on board 601 and solder balls (e.g. 403 and 405) for communicating with the devices on board 601.

In one embodiment board 601 may include devices for a connectivity system (e.g. Wi-Fi, Bluetooth, RFID, BLE, or THREAD) including an antennae and transceiver; a sensor (e.g. pressure, touch, inertial, temperature, humidity, UV, or medical); a microphone; a compass; an altimeter; or imager. The devices on board 601 would provide information to the processing system of package 501. The processing system of package 501 could also control the operation of the devices of board 601. In addition, the processing system of package 501 could provide information to the system processor system (not shown) on board 701. In some embodiments, board 701 include user interface circuitry where the devices of package 501 serves as the system processor. In some embodiments, the solder balls (403, 405) on side 201 could be located in a generic arrangement where the processing system of package 501 could be sold to a number of different component manufactures for implementation in a number of different type components.

In one embodiment, providing an integrated circuit package with solder balls on two major opposing sides of the package may enable an integrated circuit package to be implemented in a system or a component made by a third party without the use of relatively complex solder ball application equipment. With the embodiment shown, a component or system supplier manufacturing a component or system incorporating board 601 and package 501 could obtain package 501 from a package manufacturer and attach other devices to make a component or system without having to use solder ball handling equipment. For example, a Bluetooth supplier could purchase the general processing system of package 501 and install a Bluetooth transceiver and antennae on one side of package 501. They could then sell the combined Bluetooth system to a system manufacturer (e.g. tablet, smart appliance, or medical device manufacturer). In other embodiments, a system manufacturer would obtain package 501 and attached boards 601 and 701 to package 501 for implementation in their system.

In one embodiment, a method of making an integrated circuit package includes forming a work piece panel. The work piece panel includes an encapsulated panel that includes encapsulant and a plurality of die encapsulated in the encapsulated panel. For each die of the plurality of die, for at least two sides of the die, encapsulant of the encapsulated panel is located next to the side in a direction orthogonal from the side and extending out away from the die from the side.

The method includes independently attaching a first plurality of solder balls to a first major side of the work piece panel and independently attaching a second plurality of solder balls to a second major side of the work piece panel. The second major side is opposite the first major side. After the independently attaching the first plurality of solder balls and the independently attaching the second plurality of solder balls, singulating the work piece panel into a plurality of integrated circuit packages. Each of the plurality of integrated circuit packages includes at least one die of the plurality of die, at least on solder ball of the first plurality of solder balls, and at least one solder ball of the second plurality of solder balls.

In another embodiment, an integrated circuit package includes a package body. The package body includes an encapsulant and a die encapsulated in the encapsulant. For at least two sides of the die, encapsulant of the package body is located next to the side in a direction orthogonal from the side and extending out away from the die from the side. The integrated circuit package includes a first plurality of solder balls bonded only to a first major side of the package body and a second plurality of solder balls bonded only to a second major side of the package body. The second major side is opposite the first major side.

Another embodiment includes a method of making an integrated circuit package that includes forming a work piece panel. The work piece panel includes an encapsulated panel that includes encapsulant and a plurality of die encapsulated in the encapsulated panel. For each die of the plurality of die, for at least two sides of the die, encapsulant of the encapsulated panel is located next to the side in a direction orthogonal from the side and extending out away from the die from the side. The method includes applying heat to the work piece panel to bond a first plurality of solder balls to a first major side of the work piece panel. As a result of the applying heat, the first plurality of solder balls are only bonded to the work piece panel. The method includes applying heat to the work piece panel to bond a second plurality of solder balls to a second major side of the work piece panel. As a result of the applying heat, the second plurality of solder balls are only bonded to the work piece panel. The method includes after the applying heat to the work piece panel to bond a first plurality of solder balls and the applying heat to the work piece panel to bond a second plurality of solder balls, singulating the work piece panel into a plurality of integrated circuit packages. Each of the plurality of integrated circuit packages includes at least one die of the plurality of die, at least one solder ball of the first plurality of solder balls, and at least one solder ball of the second plurality of solder balls.

While particular embodiments of the present invention have been shown and described, it will be recognized to those skilled in the art that, based upon the teachings herein, further changes and modifications may be made without departing from this invention and its broader aspects, and thus, the appended claims are to encompass within their scope all such changes and modifications as are within the true spirit and scope of this invention.

1. A method of making an integrated circuit package, the method comprising:
forming a work piece panel, wherein the work piece panel includes an encapsulated panel that includes encapsulant and a plurality of die encapsulated in the encapsulated panel, wherein for each die of the plurality of die, for at least two sides of the die, encapsulant of the encapsulated panel is located next to the side in a direction orthogonal from the side and extending out away from the die from the side;
independently attaching a first plurality of solder balls to a first major side of the work piece panel;
independently attaching a second plurality of solder balls to a second major side of the work piece panel, the second major side being opposite the first major side;
after the independently attaching the first plurality of solder balls and the independently attaching the second plurality of solder balls, singulating the work piece panel into a plurality of integrated circuit packages, wherein each of the plurality of integrated circuit packages includes at least one die of the plurality of die, at least one solder ball of the first plurality of solder balls that is unencapsulated, and at least one solder ball of the second plurality of solder balls that is unencapsulated.

2. The method of claim 1 wherein the independently attaching the first plurality of solder balls includes applying the first plurality of solder balls to electrically conductive surfaces of the first major side of the work piece panel and reflowing the first plurality of solder balls to bond to the electrically conductive surfaces.

3. The method of claim 1 further comprising:
after the independently attaching the first plurality of solder balls, placing the work piece panel on a carrier with the first major side facing the carrier, wherein the independently attaching the second plurality of solder balls is performed while the work piece panel is on the carrier.

4. A method of making an integrated circuit package, the method comprising: forming a work piece panel,
wherein the work piece panel includes an encapsulated panel that includes encapsulant and a plurality of die encapsulated in the encapsulated panel, wherein for each die of the plurality of die, for at least two sides of the die, encapsulant of the encapsulated panel is located next to the side in a direction orthogonal from the side and extending out away from the die from the side;
independently attaching a first plurality of solder balls to a first major side of the work piece panel;
independently attaching a second plurality of solder balls to a second major side of the work piece panel, the second major side being opposite the first major side;
after the independently attaching the first plurality of solder balls and the independently attaching the second plurality of solder balls, singulating the work piece panel into a plurality of integrated circuit packages, wherein each of the plurality of integrated circuit packages includes at least one die of the plurality of die, at least one solder ball of the first plurality of solder balls, and at least one solder ball of the second plurality of solder balls;
after the independently attaching the first plurality of solder balls, placing the work piece panel on a carrier with the first major side facing the carrier, wherein the independently attaching the second plurality of solder balls is performed while the work piece panel is on the carrier;
wherein the carrier includes at least one opening wherein the first plurality of solder balls are located in the at least one opening when the work piece panel is on the carrier.

5. The method of claim 3 wherein a thickness of the carrier is greater than a distance of a furthest surface of the first plurality of solder balls from the first major side of the work piece panel.

6. The method of claim 1, wherein the forming the work piece panel includes forming a redistribution structure on a first major side of the encapsulated panel, the redistribution structure includes electrically conductive structures electrically coupled to electrically conductive structures of the plurality of die, wherein the independently attaching the first plurality of solder balls includes independently attaching the first plurality of solder balls to conductive surfaces of the redistribution structure.

7. The method of claim 1 wherein the encapsulated panel includes a plurality of encapsulated electrically conductive structures, wherein after singulation, each integrated circuit package of the plurality of integrated circuit packages includes at least one electrically conductive structure of the plurality of electrically conductive structures that is coupled to a solder ball of the first plurality of solder balls and a second solder ball of the second plurality of solder balls.

8. The method of claim 1 wherein after singulation, each integrated circuit package of the plurality of integrated circuit packages includes at least at least two die.

9. The method of claim 8, wherein a first die of the at least two die includes a processor and a second die of the at least two die includes a memory device, wherein the processor is operably coupled to the memory device.

10. The method of claim 1 further comprising:
after the singulating, attaching a first structure to a first major side of the integrated package wherein the attaching includes reflowing the at least one solder ball of the first plurality of solder balls to bond to at least one electrically conductive structure of the first structure, wherein the reflowing electrically couples a die of the at least one die to an electrically conductive structure of the first structure through a solder ball of the at least one solder ball that was reflowed.

11. The method of claim 10 wherein the first structure includes an integrated circuit die, wherein the die of the least one die is electrically coupled to the integrated circuit die through a reflowed solder ball of the first plurality of solder balls.

12. The method of claim 10 wherein the first structure includes a sensor, wherein the die of the least one die is electrically coupled to the sensor through a reflowed solder ball of the first plurality of solder balls.

13. The method of claim 10, wherein:
after the singulating, attaching a second structure to a second major side of the integrated circuit package, the second major side of the integrated circuit package is opposite the first major side of the integrated circuit package wherein the attaching the second structure includes reflowing the at least one solder ball of the second plurality of solder balls to bond to at least one electrically conductive structure of the second structure, wherein the reflowing electrically couples the die of the at least one die to an electrically conductive structure of the second structure through a solder ball of the at least one solder ball of the second plurality of solder balls that was reflowed.

14. The method of claim 13 wherein the second structure is characterized as a circuit board.

15. (canceled)

16. (canceled)

17. (canceled)

18. (canceled)

19. (canceled)

20. A method of making an integrated circuit package, the method comprising:
forming a work piece panel, wherein the work piece panel includes an encapsulated panel that includes encapsulant and a plurality of die encapsulated in the encapsulated panel, wherein for each die of the plurality of die, for at least two sides of the die, encapsulant of the encapsulated panel is located next to the side in a direction orthogonal from the side and extending out away from the die from the side;
applying heat to the work piece panel to bond a first plurality of solder balls to a first major side of the work piece panel, wherein as a result of the applying heat, the first plurality of solder balls are only bonded to the work piece panel;
applying heat to the work piece panel to bond a second plurality of solder balls to a second major side of the work piece panel, wherein as a result of the applying heat, the second plurality of solder balls are only bonded to the work piece panel;
after the applying heat to the work piece panel to bond a first plurality of solder balls and the applying heat to the work piece panel to bond a second plurality of solder balls, singulating the work piece panel into a plurality of integrated circuit packages, wherein each of the plurality of integrated circuit packages includes at least one die of the plurality of die, at least one solder ball of the first plurality of solder balls that is unencapsulated, and at least one solder ball of the second plurality of solder balls that is unencapsulated.
